(19) United States
(12) Patent Application Publication
(10) Pub. No.: US 2024/0319243 A1
(43) Pub. Date: Sep. 26, 2024

(54) ANALYSIS DEVICE AND RECORDING MEDIUM

(71) Applicant: Rohm Co., Ltd., Kyoto (JP)

(72) Inventor: Kenji Hamachi, Kyoto (JP)

(21) Appl. No.: 18/614,017

(22) Filed: Mar. 22, 2024

(30) Foreign Application Priority Data
Mar. 23, 2023 (JP) 2023-046850
Mar. 23, 2023 (JP) 2023-046853

(51) Int. Cl. G01R 27/28; G01R 31/28

(52) U.S. Cl. CPC G01R 27/28; G01R 31/2839

(57) ABSTRACT

An analysis device includes an extraction unit configured to use reflection characteristic and transmission characteristic included in S-parameters of a DUT measured by a series-through measurement method with a frequency characteristic measurement device, so as to extract a pole frequency, a zero point frequency, and a low frequency part of gain that can be approximated as a DC component, from gains and phases of the reflection characteristic and the transmission characteristic; and a calculation unit configured to calculate circuit constants of an equivalent circuit of the DUT, from the pole frequency, the zero point frequency, and the low frequency part. The equivalent circuit is a circuit assumed to be consisting of a capacitor connected in parallel with a serial connection body of a resistor and an inductor.

### CROSS-REFERENCE TO RELATED APPLICATIONS

This nonprovisional application claims priority under 35 U.S.C. § 119(a) on Patent Application No. 2023-046850 filed in Japan on Mar. 23, 2023 and Patent Application No. 2023-046853 filed in Japan on Mar. 23, 2023, the entire contents of which are hereby incorporated by reference.

### BACKGROUND OF THE INVENTION

### Field of the Invention

The invention disclosed in this specification relates to a technique for analyzing circuit constants of a circuit assumed to be consisting of a capacitor connected in parallel with a serial connection body of a resistor and an inductor.

### Description of Related Art

S-parameters of a circuit to be analyzed are measured by a frequency characteristic measurement device such as a vector network analyzer (see, for example, JP-A-2022-160356).

As a method of analyzing circuit constants of a circuit to be analyzed, there is a method of converting the S-parameters of the circuit to be analyzed into an impedance so that fitting or the like are performed, thereby identifying the circuit constants as lumped constants.

### BRIEF DESCRIPTION OF THE DRAWINGS

FIG. 1 is a diagram illustrating an equivalent circuit of a DUT.

FIG. 2 is a diagram illustrating a two-terminal pair circuit in a case where a series-through measurement method is performed.

FIG. 3 is a diagram illustrating gain and phase of reflection characteristic or transmission characteristic in a first pattern.

FIG. 4A is a diagram illustrating gain and phase of transmission characteristic in the first pattern.

FIG. 4B is a diagram illustrating gain and phase of reflection characteristic in the first pattern.

FIG. 5 is a diagram illustrating gain and phase of transmission characteristic or reflection characteristic in the first pattern.

FIG. 6 is a diagram illustrating gain and phase of reflection characteristic or transmission characteristic in a second pattern.

FIG. 7 is a diagram illustrating gain and phase of reflection characteristic or transmission characteristic in the second pattern.

FIG. 8 is a diagram illustrating a schematic structure of an analysis device according to a first embodiment.

FIG. 9 is a flowchart illustrating an operational example of the analysis device.

FIG. 10 is a diagram illustrating the two-terminal pair circuit in a case where a shunt-through measurement method is performed.

FIG. 11 is a diagram illustrating a schematic structure of the analysis device according to a second embodiment.

FIG. 12 is a flowchart illustrating an operational example of the analysis device according to the second embodiment.

### DETAILED DESCRIPTION OF THE PREFERRED EMBODIMENTS

### First Embodiment

### <Measurement of S-Parameters>

In a first embodiment, S-parameters of a device under test (DUT) are measured by a series-through measurement method using a frequency characteristic measurement device such as a vector network analyzer.

As a method of measuring S-parameters of a DUT, it is preferred to use a method proposed in JP-A-2022-160356, but the method is not limited to the one proposed in JP-A-2022-160356. For instance, as the method of measuring S-parameters of a DUT, it may be possible to adopt a method that needs four types of calibration boards. Here, the four types of calibration boards include a short circuited board instead of the DUT, an open circuit board instead of the DUT, a board with a load instead of the DUT, and a thru board on which a part of the DUT mounted is removed from a sample board on which the DUT is mounted.

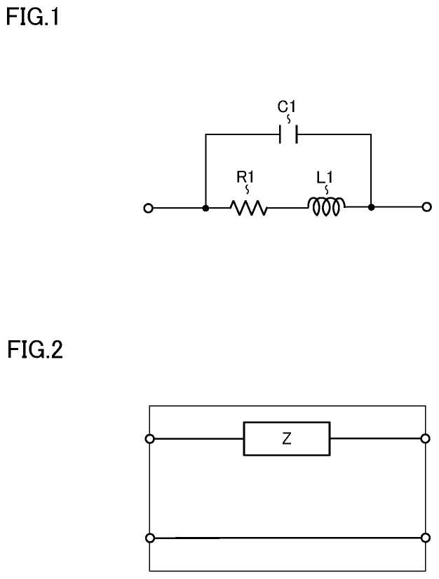

An equivalent circuit of the DUT to be analyzed by an analysis device 1 described later is the circuit illustrated in FIG. 1, i.e. a circuit assumed to be consisting of a capacitor C1 connected in parallel with a serial connection body of a resistor R1 and an inductor L1. An impedance Z of the circuit illustrated in FIG. 1 is expressed by the following equation (1), using a resistance R of the resistor R1, an inductance L of the inductor L1, a capacitance C of the capacitor C1, and a Laplace transform variable s.

$$Z = \frac{1}{\frac{1}{R + Ls} + Cs} = \frac{R + Ls}{( R + Ls ) Cs + 1} = \frac{Ls + R}{{LCs}^{2} + RCs + 1} \qquad ( 1 )$$

When a series-through measurement method is performed, the circuit illustrated in FIG. 1 can be expressed by the two-terminal pair circuit illustrated in FIG. 2. F-parameters of the two-terminal pair circuit illustrated in FIG. 2 can be expressed by the following equation (2), using the impedance Z of the circuit illustrated in FIG. 1.

$$[ \begin{matrix}{F}_{11} & {F}_{12} \\ {F}_{21} & {F}_{22}\end{matrix} ] = [ \begin{matrix}1 & Z \\ 0 & 1\end{matrix} ] \qquad ( 2 )$$

### <Analysis Method of Circuit Constants>

An analysis method that is used in the analysis device 1 described later, i.e., a method for analyzing circuit constants of the circuit illustrated in FIG. 1 is described below.

The F-parameters expressed by the above equation (2) can be converted into S-parameters like the following equation (3). Note that Z₀ in the following equation (3) represents characteristic impedance of a transmission line of the circuit illustrated in FIG. 1. A specific value of the characteristic impedance Z₀ of the transmission line of the circuit illustrated in FIG. 1 is 50 ohms, for example.

$$[ \begin{matrix}{S}_{11} & {S}_{12} \\ {S}_{21} & {S}_{22}\end{matrix} ] = \frac{1}{{F}_{11} + \frac{{F}_{12}}{{Z}_{0}} + {F}_{21} {Z}_{0} + {F}_{22}} [ \begin{matrix}{F}_{11} + \frac{{F}_{12}}{{Z}_{0}} - {F}_{21} {Z}_{0} - {F}_{22} & 2 ( {F}_{11} {F}_{22} - {F}_{21} {F}_{12} ) \\ 2 & - {F}_{11} + \frac{{F}_{12}}{{Z}_{0}} - {F}_{21} {Z}_{0} + {F}_{22}\end{matrix} ] \qquad ( 3 )$$

Further, the following equation (4) holds.

$$\frac{1}{{F}_{11} + \frac{{F}_{12}}{{Z}_{0}} + {F}_{21} {Z}_{0} + {F}_{22}} = \frac{1}{1 + \frac{Ls + R}{{LCZ}_{0} {s}^{2} + {RCZ}_{0} s + {Z}_{0}} + 1} = \frac{( 2 {CLZ}_{0} ) {s}^{2} + ( L + 2 {CRZ}_{0} ) s + R + 2 {Z}_{0}}{( {CLZ}_{0} ) {s}^{2} + ( {CRZ}_{0} ) s + {Z}_{0}} \qquad ( 4 )$$

As written above, reflection characteristics S₁₁ and S₂₂ included in the S-parameters of the circuit illustrated in FIG. 1 are expressed by the following equation (5), and transmission characteristics S₂₁ and S₁₂ included in the S-parameters of the circuit illustrated in FIG. 1 are expressed by the following equation (6).

$$\begin{matrix}{S}_{11} = {S}_{22} = \frac{Ls + R}{2 {CLZ}_{0} {s}^{2} + ( L + 2 {CRZ}_{0} ) s + R + 2 {Z}_{0}} & ( 5 ) \\ {S}_{21} = {S}_{12} = \frac{2 {CLZ}_{0} {s}^{2} + 2 {CRZ}_{0} s + 2 {Z}_{0}}{2 {CLZ}_{0} {s}^{2} + ( L + 2 {CRZ}_{0} ) s + R + 2 {Z}_{0}} & ( 6 )\end{matrix}$$

Patterns of gain and phase of reflection characteristics S₁₁ and S₂₂, and transmission characteristics S₂₁ and S₁₂ of the circuit illustrated in FIG. 1 include a first pattern and a second pattern.

The first pattern is a case where 2LZ₀/R is sufficiently smaller than L, or a case of a frequency range where |(2LZ₀/R)s| is sufficiently smaller than R. In other words, the first pattern is a case where 2Z₀/R can be regarded to be 0, or a case of a frequency range where |(2LZ₀/R²)s| can be regarded to be 0.

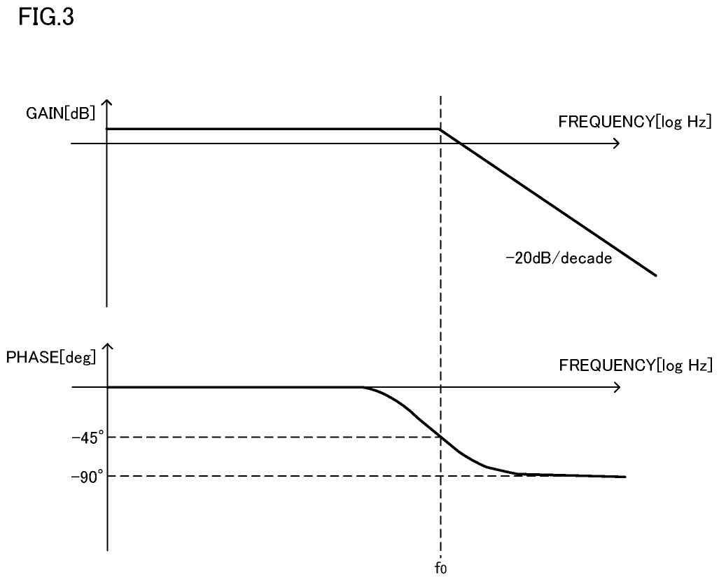

In the first pattern, the reflection characteristic S₁₁ is expressed by the following equation (7). Further, the gain and phase of the reflection characteristic S₁₁ in the first pattern is as illustrated in FIG. 3.

$${S}_{11} = \frac{Ls + R}{( Ls + R ) ( 2 {CZ}_{0} s + 1 + \frac{2 {Z}_{0}}{R} ) - \frac{2 {LZ}_{0}}{R} s} \approx \frac{1}{2 {CZ}_{0} s + 1 + \frac{2 {Z}_{0}}{R}} \qquad ( 7 )$$

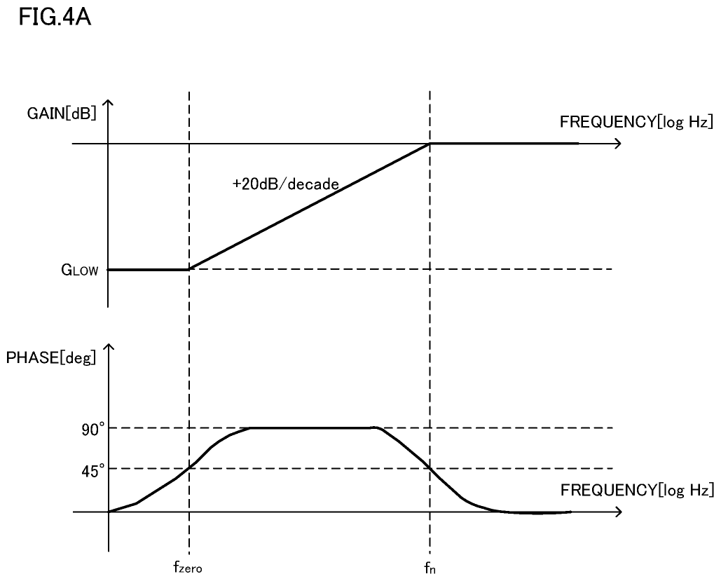

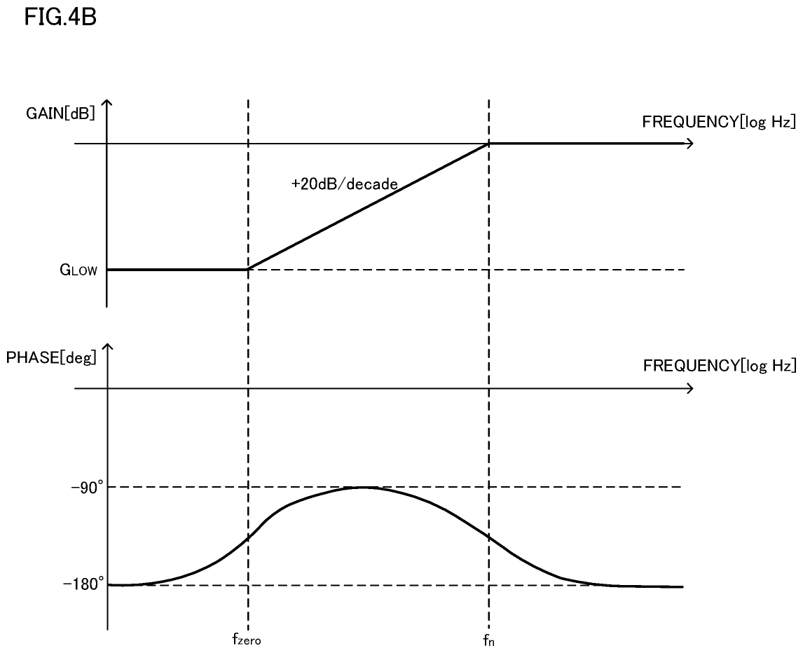

In addition, if |2LZ₀s²| is sufficiently smaller than 1 (if the frequency is generally 10¹³ (Hz) or less), the transmission characteristic S₂₁ is expressed by the following equation (8) in the first pattern. Further, if |2LZ₀s²| is sufficiently smaller than 1, the gain and phase of the transmission characteristic S₂₁ in the first pattern is as illustrated in FIG. 4A.

$${S}_{21} \approx \frac{2 {CRZ}_{0} s + 2 {Z}_{0}}{( L + 2 {CRZ}_{0} ) s + R + 2 {Z}_{0}} \qquad ( 8 )$$

A gain Grow of a low frequency part that can be approximated as a DC component, a pole frequency fₙ, and a zero point frequency f_{zero} are expressed as follows. Therefore, the resistance R of the resistor R1 is determined first from the gain G_{LOW}, the capacitance C of the capacitor C1 is determined next from the zero point frequency f_{zero}, and the inductance L of the inductor L1 is determined last from the pole frequency fₙ. Note that inflection point frequency f₀ of the gain of the reflection characteristic Sn is substantially the same as the pole frequency fₙ, and hence the inflection point frequency f₀ of the gain of the reflection characteristic Su may be referred to, if the pole frequency fₙ can be hardly extracted or in other case.

$${G}_{LOW} = 20 {log}_{10} \vert \frac{2 {Z}_{0}}{R + 2 {Z}_{0}} \vert ( dB ) \\ {f}_{n} = \frac{1}{2 π} \cdot \frac{R + 2 {Z}_{0}}{L + 2 {CRZ}_{0}} ( Hz ) \\ {f}_{zero} = \frac{1}{2 π} \cdot \frac{1}{CR} ( Hz ) \\ {f}_{0} = \frac{1}{2 π} \cdot \frac{1 + \frac{2 {Z}_{0}}{R}}{2 {CZ}_{0}} ( Hz )$$

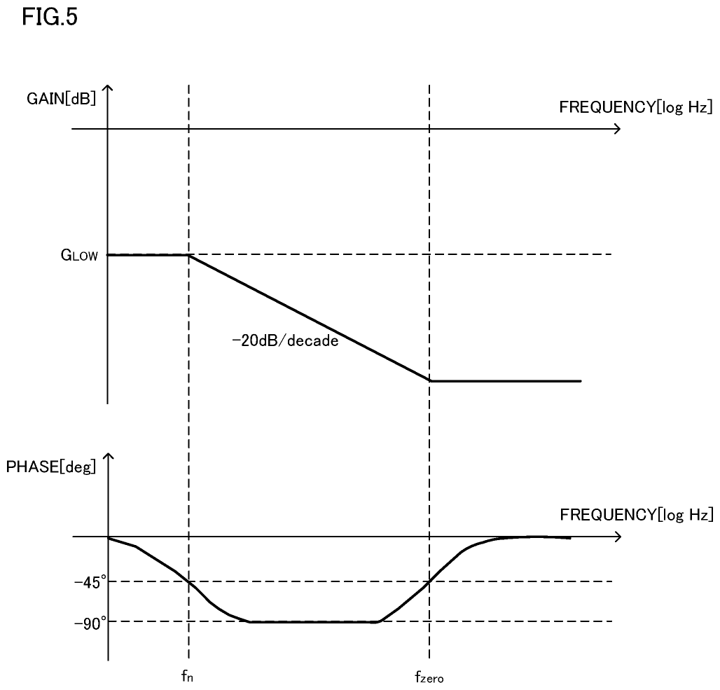

Depending on a combination of the resistance R of the resistor R1, the inductance L of the inductor L1, and the capacitance C of the capacitor C1, the zero point frequency f_{zero} may be higher than the pole frequency fₙ. In this case, the gain and phase of the transmission characteristic S₂₁ in the first pattern is as illustrated in FIG. 5.

The second pattern is a case where 2LZ₀/R is not sufficiently smaller than L, or a case of a frequency range where |(2LZ₀/R)s| is not sufficiently smaller than R. In other words, the second pattern is a case where 2Z₀/R cannot be regarded to be 0, or a case of a frequency range where |(2LZ₀/R²)s| cannot be regarded to be 0.

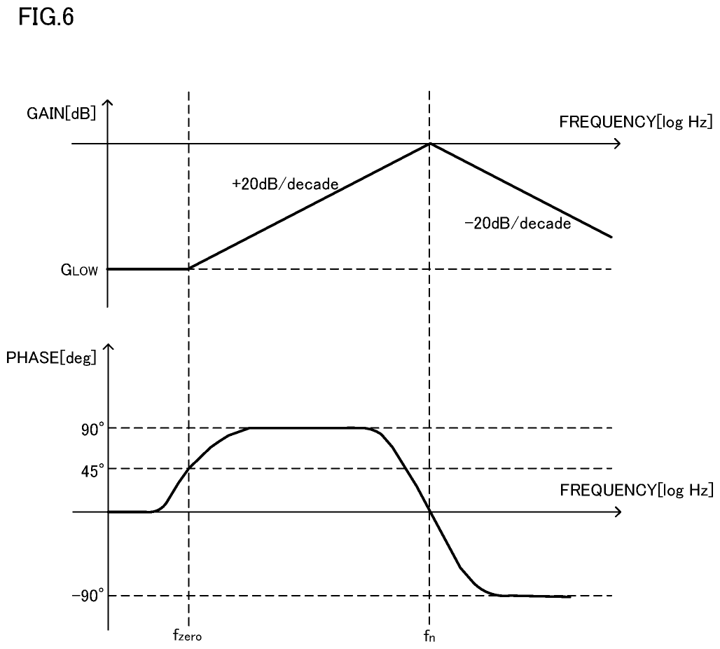

In the second pattern, the reflection characteristic S₁₁ is expressed by the following equation (9). Further, the gain and phase of the reflection characteristic S₁₁ in the second pattern is as illustrated in FIG. 6.

Note that in the second pattern, it is difficult to exploit the transmission characteristic S₂₁. The term of s² in the denominator of the transmission characteristic S₂₁ can be omitted only if the frequency is 10⁹ (Hz) or less, and the term of s² in the denominator of the transmission characteristic S₂₁ can be omitted only if the frequency is 10⁶ (Hz) or less. Further, a frequency measurement range of a general frequency characteristic measurement device is higher than 10⁶ (Hz), and a general frequency characteristic measurement device cannot measure 10⁶ (Hz) or less. In addition, even if the frequency characteristic measurement device that can measure 10⁶ (Hz) or less is used, the measurement of 10⁶ (Hz) or less takes time because of low frequencies.

$${S}_{11} = \frac{1}{2 {CLZ}_{0}} \cdot \frac{Ls + R}{{s}^{2} + ( \frac{1}{2 {CZ}_{0}} + \frac{R}{L} ) s + \frac{R}{2 {CLZ}_{0}} + \frac{1}{CL}} \qquad ( 9 )$$

Here, the reflection characteristic S₁₁ is also expressed as follows.

$${S}_{11} = \frac{1}{2 {CLZ}_{0}} \cdot ( Ls + R ) \cdot \frac{{ω}_{n}^{2}}{{s}^{2} + 2 {ζω}_{n} s + {ω}_{n}^{2}}$$

Then, the pole frequency fₙ is expressed as follows.

$${ω}_{n} = \sqrt{\frac{R}{2 {CLZ}_{0}} + \frac{1}{CL}} ( rad / s ) \\ {f}_{n} = \frac{1}{2 π} {ω}_{n} = \frac{1}{2 π} \sqrt{\frac{R}{2 {CLZ}_{0}} + \frac{1}{CL}} ( Hz )$$

In addition, the zero point frequency f_{zero} is expressed as follows, and the gain G_{LOW} of the low frequency part that can be approximated as a DC component is expressed as follows.

$${f}_{zero} = \frac{1}{2 π} \cdot \frac{R}{L} ( Hz ) \\ {G}_{LOW} = 20 {log}_{10} \vert \frac{R}{R + 2 {Z}_{0}} \vert ( dB )$$

Therefore, the resistance R of the resistor R1 is determined first from the gain G_{LOW}, the capacitance C of the capacitor C1 is determined next from the zero point frequency f_{zero}, and the inductance L of the inductor L1 is determined last from the pole frequency fₙ.

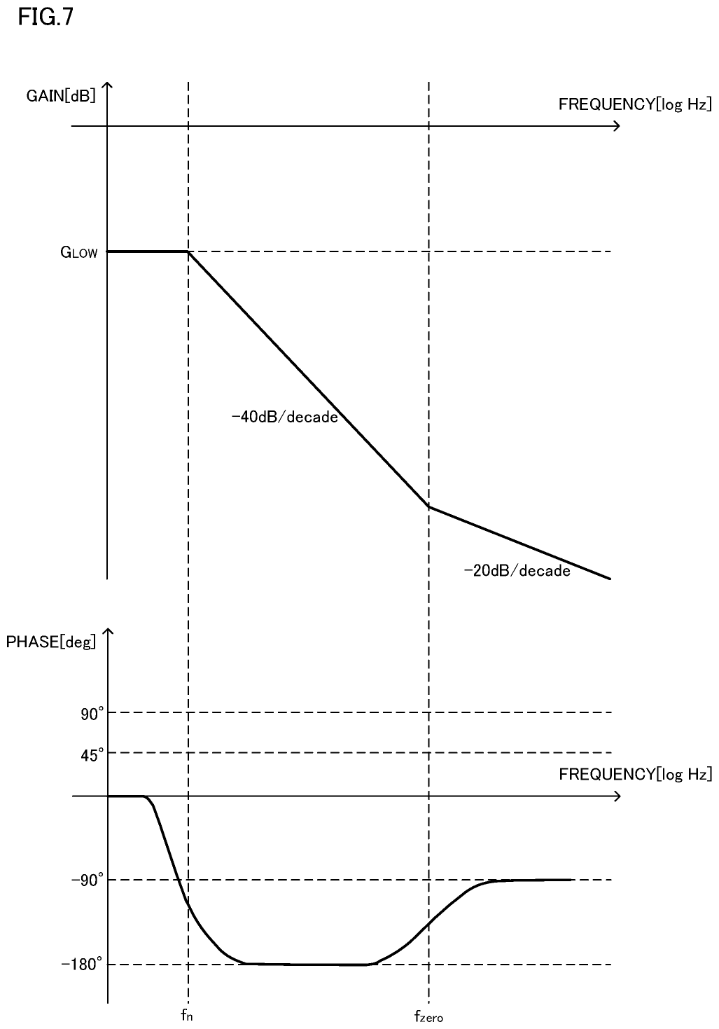

Depending on a combination of the resistance R of the resistor R1, the inductance L of the inductor L1, and the capacitance C of the capacitor C1, the zero point frequency f_{zero} may be higher than the pole frequency fₙ. In this case, the gain and phase of the reflection characteristic S₁₁ in the second pattern is as illustrated in FIG. 7.

### <Analysis Device>

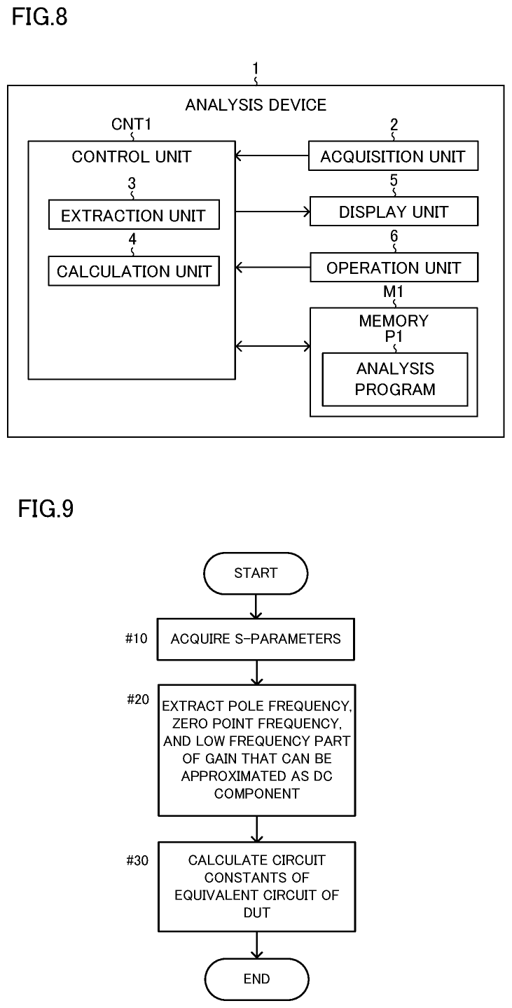

FIG. 8 is a diagram illustrating a schematic structure of the analysis device according to the first embodiment. The analysis device 1 illustrated in FIG. 8 includes an acquisition unit 2, an extraction unit 3, a calculation unit 4, a display unit 5, and an operation unit 6.

The analysis device 1 illustrated in FIG. 8 includes a control unit CNT1 such as a microcomputer, and a memory M1 such as a random access memory (RAM) or a read only memory (ROM). The memory M1 stores an analysis program P1. When the control unit CNT1 executes the analysis program P1, the control unit CNT1 functions as the extraction unit 3 and the calculation unit 4.

The acquisition unit 2 acquires the S-parameters of the DUT measured by the series-through measurement method with the frequency characteristic measurement device. The acquisition unit 2 may be a communication interface that communicates with the frequency characteristic measurement device, for example, or a data reading unit or the like that can read data from a portable storage medium storing the S-parameters of the DUT.

The extraction unit 3 uses the reflection characteristic and the transmission characteristic included in the S-parameters of the DUT acquired by the acquisition unit 2, so as to extract the pole frequency fₙ, the zero point frequency f_{zero}, and the low frequency part of the gain (the gain G_{LOW}) that can be approximated as the DC component, from the gains and the phases of the reflection characteristic and the transmission characteristic. The extraction unit 3 may extract the pole frequency fₙ, the zero point frequency f_{zero}, and the low frequency part of the gain (the gain G_{LOW}) that can be approximated as the DC component, on the basis of a signal output from the operation unit 6 such as a keyboard, or a pointing device (a signal corresponding to an operation by a user). In addition, the extraction unit 3 may refer to frequency characteristics of the gains and the phases of the reflection characteristic and the transmission characteristic, so as to automatically extract the pole frequency fₙ, the zero point frequency f_{zero}, and the low frequency part of the gain (the gain G_{LOW}) that can be approximated as the DC component.

The calculation unit 4 calculates the circuit constants of the equivalent circuit of the DUT (the resistance R of the resistor R1, the inductance L of the inductor L1, the capacitance C of the capacitor C1), from the pole frequency fₙ, the zero point frequency f_{zero}, and the low frequency part of the gain (the gain G_{LOW}) that can be approximated as the DC component.

The display unit 5 displays, for example, a graph indicating frequency characteristics of the gains and the phases of the reflection characteristic and the transmission characteristic (the graph illustrated in FIG. 3 or the like). The user refers to display content on the display unit 5, and can operate the operation unit 6 so as to extract the pole frequency fₙ, the zero point frequency f_{zero}, and the low frequency part of the gain (the gain G_{LOW}) that can be approximated as the DC component.

The calculation unit 4 determines which one of the first pattern and the second pattern the gains of the reflection characteristic and the transmission characteristic are. The calculation unit 4 may determine which one of the first pattern and the second pattern the gains of the reflection characteristic and the transmission characteristic are, on the basis of the signal output from the operation unit 6 (the signal corresponding to the operation by the user). In addition, the calculation unit 4 may refer to the frequency characteristics of the gains and the phases of the reflection characteristic and the transmission characteristic, so as to automatically determine which one of the first pattern and the second pattern the gains of the reflection characteristic and the transmission characteristic are.

For instance, if a phase of the reflection characteristic is less than 180 degrees, the calculation unit 4 determines that the gains of the reflection characteristic and the transmission characteristic are the first pattern, while if the phase of the reflection characteristic is 180 degrees or more, the calculation unit 4 determines that the gains of the reflection characteristic and the transmission characteristic are the second pattern.

FIG. 9 is a flowchart illustrating an operational example of the analysis device 1. First, the acquisition unit 2 of the analysis device 1 acquires the S-parameters of the DUT measured by the series-through measurement method with the frequency characteristic measurement device (Step #10). Next, the extraction unit 3 of the analysis device 1 extracts the pole frequency fₙ, the zero point frequency f_{zero}, and the low frequency part of the gain (the gain G_{LOW}) that can be approximated as the DC component, from the gains and the phases of the reflection characteristic and the transmission characteristic (Step #20). Further, the calculation unit 4 of the analysis device 1 calculates the circuit constants of the equivalent circuit of the DUT (Step #30), and finishes the flow operation.

When converting the S-parameters into impedance, the analysis device 1 can calculate the circuit constants of the equivalent circuit of the DUT, without a process of discarding a part of data, and hence the circuit constants of the equivalent circuit of the DUT can be analyzed well.

### Second Embodiment

### <Measurement of S-Parameter>

In the second embodiment, the S-parameters of the device under test (DUT) are measured by the shunt-through measurement method with the frequency characteristic measurement device such as a vector network analyzer.

Although the method proposed in JP-A-2022-160356 is preferred as the method of measuring the S-parameters of the DUT, the method proposed in JP-A-2022-160356 is not a limitation. For instance, as the method of measuring the S-parameters of the DUT, it may be possible to adopt a method that needs four types of calibration boards. Here, the four types of calibration boards include a short circuited board instead of the DUT, an open circuit board instead of the DUT, a board with a load instead of the DUT, and a thru board on which a part of the DUT mounted is removed from a sample board on which the DUT is mounted.

The equivalent circuit of the DUT as an analysis target of an analysis device 11 described later is the circuit illustrated in FIG. 1, i.e. the circuit assumed to be consisting of the capacitor C1 connected in parallel with the serial connection body of the resistor R1 and the inductor L1. The impedance Z of the circuit illustrated in FIG. 1 is expressed by the following equation (10), using the resistance R of the resistor R1, the inductance L of the inductor L1, the capacitance C of the capacitor C1, and the Laplace transform variable s.

$$Z = \frac{1}{\frac{1}{R + Ls} + Cs} = \frac{R + Ls}{( R + Ls ) Cs + 1} = \frac{Ls + R}{{LCs}^{2} + RCs + 1} \qquad ( 10 )$$

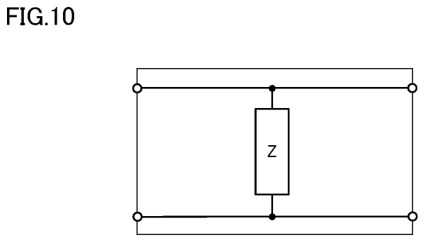

When the shunt-through measurement method is performed, the circuit illustrated in FIG. 1 can be expressed by the two-terminal pair circuit illustrated in FIG. 10. The F-parameters of the two-terminal pair circuit illustrated in FIG. 10 can be expressed by the following equation (11), using the impedance Z of the circuit illustrated in FIG. 1.

$$[ \begin{matrix}{F}_{11} & {F}_{12} \\ {F}_{21} & {F}_{22}\end{matrix} ] = [ \begin{matrix}1 & 0 \\ 1 / Z & 1\end{matrix} ] \qquad ( 11 )$$

### <Analysis Method of Circuit Constants>

An analysis method that is used in the analysis device 11 described later, i.e., a method for analyzing the circuit constants of the circuit illustrated in FIG. 1 is described below.

The F-parameters expressed by the above equation (11) can be converted into the S-parameters like the following equation (12). Note that Z₀ in the following equation (12) represents characteristic impedance of a transmission line of the circuit illustrated in FIG. 1. A specific value of the characteristic impedance Z₀ of the transmission line of the circuit illustrated in FIG. 1 is 50 ohms, for example.

$$[ \begin{matrix}{S}_{11} & {S}_{12} \\ {S}_{21} & {S}_{22}\end{matrix} ] = \frac{1}{{F}_{11} + \frac{{F}_{12}}{{Z}_{0}} + {F}_{21} {Z}_{0} + {F}_{22}} [ \begin{matrix}{F}_{11} + \frac{{F}_{12}}{{Z}_{0}} - {F}_{21} {Z}_{0} - {F}_{22} & 2 ( {F}_{11} {F}_{22} - {F}_{21} {F}_{12} ) \\ 2 & - {F}_{11} + \frac{{F}_{12}}{{Z}_{0}} - {F}_{21} {Z}_{0} + {F}_{22}\end{matrix} ] \qquad ( 12 )$$

Further, the following equation (13) holds.

$$\frac{1}{{F}_{11} + \frac{{F}_{12}}{{Z}_{0}} + {F}_{21} {Z}_{0} + {F}_{22}} = \frac{{CLZ}_{0} {s}^{2} + ( 2 L + {CRZ}_{0} ) s + 2 R + {Z}_{0}}{Ls + R} \qquad ( 13 )$$

As written above, the reflection characteristics S₁₁ and S₂₂ included in the S-parameters of the circuit illustrated in FIG. 1 are expressed by the following equation (14), and the transmission characteristics S₂₁ and S₁₂ included in the S-parameters of the circuit illustrated in FIG. 1 are expressed by the following equation (15).

$$\begin{matrix}{S}_{11} = {S}_{22} = - \frac{{CLZ}_{0} {s}^{2} + {CRZ}_{0} s + {Z}_{0}}{{CLZ}_{0} {s}^{2} + ( 2 L + {CRZ}_{0} ) s + 2 R + {Z}_{0}} & ( 14 ) \\ {S}_{21} = {S}_{12} = \frac{2 Ls + R}{{CLZ}_{0} {s}^{2} + ( 2 L + {CRZ}_{0} ) s + 2 R + {Z}_{0}} & ( 15 )\end{matrix}$$

The patterns of the gain and phase of the reflection characteristics S₁₁ and S₂₂, and the transmission characteristics S₂₁ and S₁₂ of the circuit illustrated in FIG. 1 include the first pattern and the second pattern.

The first pattern is a case where LZ₀/R is sufficiently smaller than 2L, or a case of a frequency range where |(LZ₀/R)s| is sufficiently smaller than 2R. In other words, the first pattern is a case where Z₀/(2R) can be regarded to be 0, or a case of a frequency range where |(LZ₀/(2R²))s| can be regarded to be 0.

In the first pattern, the transmission characteristic S₂₁ is expressed by the following equation (16). Further, the gain and phase of the transmission characteristic S₂₁ in the first pattern is as illustrated in FIG. 3.

$${S}_{21} = \frac{2 ( Ls + R )}{( Ls + R ) ( {CZ}_{0} s + 2 + \frac{{Z}_{0}}{R} ) - \frac{{LZ}_{0}}{R} s} \approx \frac{2}{{CZ}_{0} s + 2 + \frac{{Z}_{0}}{R}} \qquad ( 16 )$$

In addition, if |CLZ₀s²| is sufficiently smaller than 1 (if the frequency is generally 10¹³ (Hz) or less), the reflection characteristic Sn is expressed by the following equation (17) in the first pattern. Further, if |CLZ₀s²| is sufficiently smaller than 1, the gain and phase of the reflection characteristic Su in the first pattern is as illustrated in FIG. 4B.

$${S}_{11} \approx \frac{{CRZ}_{0} s + {Z}_{0}}{( 2 L + {CRZ}_{0} ) s + 2 R + {Z}_{0}} \qquad ( 17 )$$

The gain Grow of a low frequency part that can be approximated as a DC component, the pole frequency fₙ, and the zero point frequency f_{zero} are expressed as follows. Therefore, the resistance R of the resistor R1 is determined first from the gain Grow, the capacitance C of the capacitor C1 is determined next from the zero point frequency f_{zero}, and the inductance L of the inductor L1 is determined last from the pole frequency fₙ. Note that the inflection point frequency f₀ of the gain of the transmission characteristic S₂₁ is substantially the same as the pole frequency fₙ, and hence the inflection point frequency f₀ of the gain of the transmission characteristic S₂₁ may be referred to, if the pole frequency fₙ can be hardly extracted or in other case.

$${G}_{LOW} = 20 {log}_{10} \vert \frac{{Z}_{0}}{2 R + {Z}_{0}} \vert ( dB ) \\ {f}_{n} = \frac{1}{2 π} \cdot \frac{2 R + {Z}_{0}}{2 L + {CRZ}_{0}} ( Hz ) \\ {f}_{zero} = \frac{1}{2 π} \cdot \frac{1}{CR} ( Hz ) \\ {f}_{0} = \frac{1}{2 π} \cdot \frac{2 + \frac{{Z}_{0}}{R}}{{CZ}_{0}} ( Hz )$$

Depending on a combination of the resistance R of the resistor R1, the inductance L of the inductor L1, and the capacitance C of the capacitor C1, the zero point frequency f_{zero} may be higher than the pole frequency fₙ. In this case, the gain and phase of the reflection characteristic Su in the first pattern is as illustrated in FIG. 5.

The second pattern is a case where LZ₀/R is not sufficiently smaller than 2L, or a case of a frequency range where |(LZ₀/R)s| is not sufficiently smaller than 2R. In other words, the second pattern is a case where Z₀/(2R) cannot be regarded to be 0, or a case of a frequency range where |(LZ₀/(2R²))s| cannot be regarded to be 0.

In the second pattern, the transmission characteristic S₂₁ is expressed by the following equation (18). Further, the gain and phase of the transmission characteristic S₂₁ in the second pattern is as illustrated in FIG. 6.

Note that it is difficult to exploit the reflection characteristic S₁₁ in the second pattern. The term of s² in the denominator of the reflection characteristic Su can be omitted only if the frequency is 10⁹ (Hz) or less, and the term of s² in the denominator of the reflection characteristic S₁₁ can be omitted only if the frequency is 10⁶ (Hz) or less. Further, a frequency measurement range of a general frequency characteristic measurement device is higher than 10⁶ (Hz), and a general frequency characteristic measurement device cannot measure 10⁶ (Hz) or less. In addition, even if the frequency characteristic measurement device that can measure 10⁶ (Hz) or less is used, the measurement of 10⁶ (Hz) or less takes time because of low frequencies.

$${S}_{21} = \frac{2}{{CLZ}_{0}} \cdot \frac{Ls + R}{{s}^{2} + ( \frac{2}{{CZ}_{0}} + \frac{R}{L} ) s + \frac{2 R}{{CLZ}_{0}} + \frac{1}{CL}} \qquad ( 18 )$$

Here, the transmission characteristic S₂₁ is also expressed as follows.

$${S}_{21} = \frac{2}{{CLZ}_{0}} \cdot ( Ls + R ) \cdot \frac{{ω}_{n}^{2}}{{s}^{2} + 2 {ζω}_{n} s + {ω}_{n}^{2}}$$

Then, the pole frequency fₙ is expressed as follows.

$${ω}_{n} = \sqrt{\frac{2 R}{{CLZ}_{0}} + \frac{1}{CL}} ( rad / s ) \\ {f}_{n} = \frac{1}{2 π} {ω}_{n} = \frac{1}{2 π} \sqrt{\frac{2 R}{{CLZ}_{0}} + \frac{1}{CL}} ( Hz )$$

In addition, the zero point frequency f_{zero} is expressed as follows, and the gain G_{LOW} of the low frequency part that can be approximated as a DC component is expressed as follows.

$${f}_{zero} = \frac{1}{2 π} \cdot \frac{R}{L} ( Hz ) \\ {G}_{LOW} = 20 {log}_{10} \vert \frac{2 R}{2 R + {Z}_{0}} \vert ( dB )$$

Therefore, the resistance R of the resistor R1 is determined first from the gain G_{LOW}, the capacitance C of the capacitor C1 is determined next from the zero point frequency f_{zero}, and the inductance L of the inductor L1 is determined last from the pole frequency fₙ.

Depending on a combination of the resistance R of the resistor R1, the inductance L of the inductor L1, and the capacitance C of the capacitor C1, the zero point frequency f_{zero} may be higher than the pole frequency fₙ. In this case, the gain and phase of the transmission characteristic S₂₁ in the second pattern is as illustrated in FIG. 7.

### <Analysis Device>

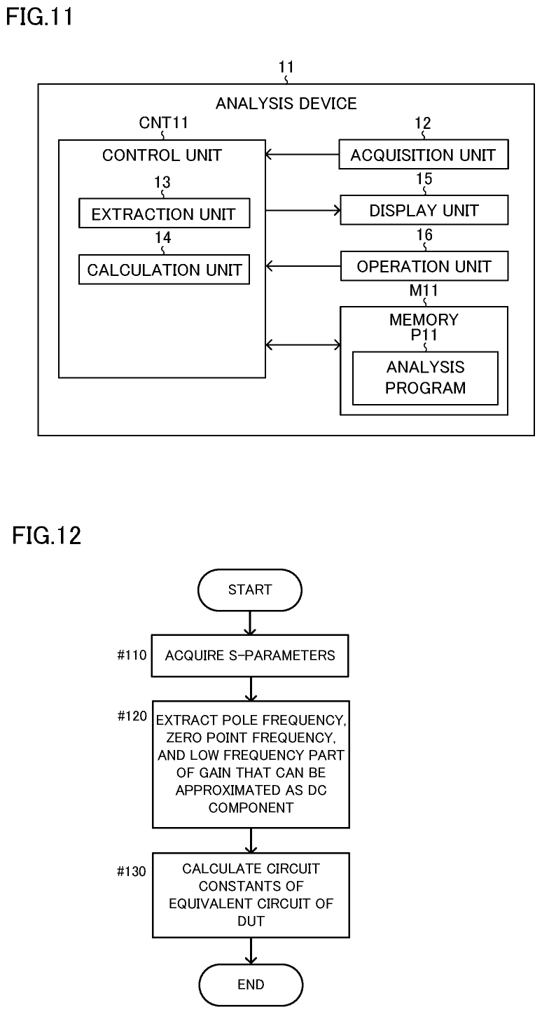

FIG. 11 is a diagram illustrating a schematic structure of the analysis device according to the second embodiment. The analysis device 11 illustrated in FIG. 11 includes an acquisition unit 12, an extraction unit 13, a calculation unit 14, a display unit 15, and an operation unit 16.

The analysis device 11 illustrated in FIG. 11 includes a control unit CNT11 such as a microcomputer, and a memory M11 such as a random access memory (RAM) or a read only memory (ROM). The memory M11 stores an analysis program P11. When the control unit CNT11 executes the analysis program P11, the control unit CNT11 functions as the extraction unit 13 and the calculation unit 14.

The acquisition unit 12 acquires the S-parameters of the DUT measured by the shunt-through measurement method with the frequency characteristic measurement device. The acquisition unit 12 may be a communication interface that communicates with the frequency characteristic measurement device, for example, or a data reading unit or the like that can read data from a portable storage medium storing the S-parameters of the DUT.

The extraction unit 13 uses the reflection characteristic and the transmission characteristic included in the S-parameters of the DUT acquired by the acquisition unit 12, so as to extract the pole frequency fₙ, the zero point frequency f_{zero}, and the low frequency part of the gain (the gain G_{LOW}) that can be approximated as the DC component, from the gains and the phases of the reflection characteristic and the transmission characteristic. The extraction unit 13 may extract the pole frequency fₙ, the zero point frequency f_{zero}, and the low frequency part of the gain (the gain G_{LOW}) that can be approximated as the DC component, on the basis of a signal output from the operation unit 16 such as a keyboard, or a pointing device (the signal corresponding to the operation by the user). In addition, the extraction unit 13 may refer to frequency characteristics of the gains and the phases of the reflection characteristic and the transmission characteristic, so as to automatically extract the pole frequency fₙ, the zero point frequency f_{zero}, and the low frequency part of the gain (the gain G_{LOW}) that can be approximated as the DC component.

The calculation unit 14 calculates the circuit constants of the equivalent circuit of the DUT (the resistance R of the resistor R1, the inductance L of the inductor L1, the capacitance C of the capacitor C1), from the pole frequency fₙ, the zero point frequency f_{zero}, and the low frequency part of the gain (the gain G_{LOW}) that can be approximated as the DC component.

The display unit 15 displays, for example, a graph indicating frequency characteristics of the gains and the phases of the reflection characteristic and the transmission characteristic (the graph illustrated in FIG. 3 or the like). The user refers to display content on the display unit 15, and can operate the operation unit 16 so as to extract the pole frequency fₙ, the zero point frequency f_{zero}, and the low frequency part of the gain (the gain G_{LOW}) that can be approximated as the DC component.

The calculation unit 14 determines which one of the first pattern and the second pattern the gains of the reflection characteristic and the transmission characteristic are. The calculation unit 14 may determine which one of the first pattern and the second pattern the gains of the reflection characteristic and the transmission characteristic are, on the basis of the signal output from the operation unit 16 (the signal corresponding to the operation by the user). In addition, the calculation unit 14 may refer to the frequency characteristics of the gains and the phases of the reflection characteristic and the transmission characteristic, so as to automatically determine which one of the first pattern and the second pattern the gains of the reflection characteristic and the transmission characteristic are.

For instance, if a phase of the transmission characteristic is less than 180 degrees, the calculation unit 14 determines that the gains of the reflection characteristic and the transmission characteristic are the first pattern, while if the phase of the transmission characteristic is 180 degrees or more, the calculation unit 14 determines that the gains of the reflection characteristic and the transmission characteristic are the second pattern.

FIG. 12 is a flowchart illustrating an operational example of the analysis device 11. First, the acquisition unit 12 of the analysis device 11 acquires the S-parameters of the DUT measured by the shunt-through measurement method with the frequency characteristic measurement device (Step #110). Next, the extraction unit 13 of the analysis device 11 extracts the pole frequency fₙ, the zero point frequency f_{zero}, and the low frequency part of the gain (the gain G_{LOW}) that can be approximated as the DC component, from the gains and the phases of the reflection characteristic and the transmission characteristic (Step #120). Further, the calculation unit 14 of the analysis device 11 calculates the circuit constants of the equivalent circuit of the DUT (Step #130), and finishes the flow operation.

When converting the S-parameters into impedance, the analysis device 11 can calculate the circuit constants of the equivalent circuit of the DUT, without a process of discarding a part of data, and hence the circuit constants of the equivalent circuit of the DUT can be analyzed well.

### Others

Other than the embodiments described above, the structure of the invention can be variously modified within the scope of the invention without deviating from the spirit thereof. The embodiments described above are merely examples in all aspects, and should not be interpreted as limitations. The technical scope of the present invention is defined not by the above description of the embodiments but by the claims, and should be understood to include all modifications within the meaning and scope equivalent to the claims.

### ADDITIONAL REMARKS

As for the present disclosure, for which specific structural examples are shown in the embodiments described above, additional remarks are described below.

An analysis device (1) according to a first aspect of the present disclosure has the following structure (first structure). The analysis device (1) includes an extraction unit (3) configured to use reflection characteristic and transmission characteristic included in S-parameters of a DUT measured by a series-through measurement method with a frequency characteristic measurement device, which measures a circuit assumed to be consisting of a capacitor connected in parallel with a serial connection body of a resistor and an inductor, so as to extract a pole frequency, a zero point frequency, and a low frequency part of gain that can be approximated as a DC component, from gains and phases of the reflection characteristic and the transmission characteristic; and a calculation unit (4) configured to calculate circuit constants of an equivalent circuit of the DUT, from the pole frequency, the zero point frequency, and the low frequency part. The equivalent circuit is a circuit assumed to be consisting of a capacitor (C1) connected in parallel with a serial connection body of a resistor (R1) and an inductor (L1).

In the analysis device having the first structure described above, it may be possible to adopt the following structure (second structure). Patterns of the gains and the phases of the reflection characteristic and the transmission characteristic include a first pattern and a second pattern. If the gains and the phases of the reflection characteristic and the transmission characteristic are the first pattern, the calculation unit uses the transmission characteristic, and if the gains and the phases of the reflection characteristic and the transmission characteristic are the second pattern, the calculation unit uses the reflection characteristic.

In the analysis device having the second structure described above, it may be possible to adopt the following structure (third structure). If the gains and the phases of the reflection characteristic and the transmission characteristic are the first pattern, the phase of the reflection characteristic is less than 180 degrees. If the gains and the phases of the reflection characteristic and the transmission characteristic are the second pattern, the phase of the reflection characteristic is 180 degrees or more.

In the analysis device having the second or third structure described above, it may be possible to adopt the following structure (fourth structure). If the gains and the phases of the reflection characteristic and the transmission characteristic are the first pattern, the calculation unit regards that 2Z₀/R is 0, where Z₀ is characteristic impedance of a transmission line of the circuit, and R is resistance of the resistor.

In the analysis device having the second or third structure described above, it may be possible to adopt the following structure (fifth structure). If the gains and the phases of the reflection characteristic and the transmission characteristic are the first pattern, the calculation unit regards that |(2LZ₀/R²)s| is 0, where L is inductance of the inductor, Z₀ is characteristic impedance of a transmission line of the circuit, R is resistance of the resistor, and s is Laplace transform variable.

In the analysis device having any one of the second to fifth structures described above, it may be possible to adopt the following structure (sixth structure). If the gains and the phases of the reflection characteristic and the transmission characteristic are the second pattern, the calculation unit does not regard that 2Z₀/R is 0, where Z₀ is characteristic impedance of a transmission line of the circuit, and R is resistance of the resistor.

An analysis program according to a first aspect of the present disclosure has the following structure (seventh structure). The analysis program allows a computer to function as an extraction unit (3) configured to use reflection characteristic and transmission characteristic included in S-parameters of a DUT measured by a series-through measurement method with a frequency characteristic measurement device, so as to extract a pole frequency, a zero point frequency, and a low frequency part of gain that can be approximated as a DC component, from gains and phases of the reflection characteristic and the transmission characteristic; and a calculation unit (4) configured to calculate circuit constants of an equivalent circuit of the DUT, from the pole frequency, the zero point frequency, and the low frequency part. The equivalent circuit is a circuit assumed to be consisting of a capacitor connected in parallel with a serial connection body of a resistor and an inductor.

An analysis device (11) according to a second aspect of the present disclosure has the following structure (eighth structure). The analysis device (11) includes an extraction unit (13) configured to use reflection characteristic and transmission characteristic included in S-parameters of a DUT measured by a shunt-through measurement method with a frequency characteristic measurement device, which measures a circuit assumed to be consisting of a capacitor connected in parallel with a serial connection body of a resistor and an inductor, so as to extract a pole frequency, a zero point frequency, and a low frequency part of gain that can be approximated as a DC component, from gains and phases of the reflection characteristic and the transmission characteristic; and a calculation unit (14) configured to calculate circuit constants of an equivalent circuit of the DUT, from the pole frequency, the zero point frequency, and the low frequency part. The equivalent circuit is a circuit assumed to be consisting of a capacitor (C1) connected in parallel with a serial connection body of a resistor (R1) and an inductor (L1).

In the analysis device having the eighth structure described above, it may be possible to adopt the following structure (ninth structure). Patterns of the gains and the phases of the reflection characteristic and the transmission characteristic include a first pattern and a second pattern. If the gains and the phases of the reflection characteristic and the transmission characteristic are the first pattern, the calculation unit uses the reflection characteristic. If the gains and the phases of the reflection characteristic and the transmission characteristic are the second pattern, the calculation unit uses the transmission characteristic.

In the analysis device having the ninth structure described above, it may be possible to adopt the following structure (tenth structure). If the gains and the phases of the reflection characteristic and the transmission characteristic are the first pattern, the phase of the transmission characteristic is less than 180 degrees. If the gains and the phases of the reflection characteristic and the transmission characteristic are the second pattern, the phase of the transmission characteristic is 180 degrees or more.

In the analysis device having the ninth or tenth structure described above, it may be possible to adopt the following structure (eleventh structure). If the gains and the phases of the reflection characteristic and the transmission characteristic are the first pattern, the calculation unit regards that Z₀/(2R) is 0, where Z₀ is characteristic impedance of a transmission line of the circuit, and R is resistance of the resistor.

In the analysis device having the ninth or tenth structure described above, it may be possible to adopt the following structure (twelfth structure). If the gains and the phases of the reflection characteristic and the transmission characteristic are the first pattern, the calculation unit regards that |(LZ₀/(2R²))s| is 0, where Lis inductance of the inductor, Z₀ is characteristic impedance of a transmission line of the circuit, R is resistance of the resistor, and s is Laplace transform variable.

In the analysis device having any one of the ninth to twelfth structures described above, it may be possible to adopt the following structure (thirteenth structure). If the gains and the phases of the reflection characteristic and the transmission characteristic are the second pattern, the calculation unit does not regard that Z₀/(2R) is 0, where Z₀ is characteristic impedance of a transmission line of the circuit, and R is resistance of the resistor.

An analysis program according to a second aspect of the present disclosure has the following structure (fourteenth structure). The analysis program allows a computer to function as an extraction unit (13) configured to use reflection characteristic and transmission characteristic included in S-parameters of a DUT measured by a shunt-through measurement method with a frequency characteristic measurement device, so as to extract a pole frequency, a zero point frequency, and a low frequency part of gain that can be approximated as a DC component, from gains and phases of the reflection characteristic and the transmission characteristic; and a calculation unit (14) configured to calculate circuit constants of an equivalent circuit of the DUT, from the pole frequency, the zero point frequency, and the low frequency part. The equivalent circuit is a circuit assumed to be consisting of a capacitor connected in parallel with a serial connection body of a resistor and an inductor.

What is claimed is:

1. An analysis device comprising:
an extraction unit configured to use reflection characteristic and transmission characteristic included in S-parameters of a DUT measured by a series-through measurement method with a frequency characteristic measurement device, so as to extract a pole frequency, a zero point frequency, and a low frequency part of gain that can be approximated as a DC component, from gains and phases of the reflection characteristic and the transmission characteristic; and
a calculation unit configured to calculate circuit constants of an equivalent circuit of the DUT, from the pole frequency, the zero point frequency, and the low frequency part, wherein
the equivalent circuit is a circuit assumed to be consisting of a capacitor connected in parallel with a serial connection body of a resistor and an inductor.

2. The analysis device according to claim 1, wherein
patterns of the gains and the phases of the reflection characteristic and the transmission characteristic include a first pattern and a second pattern,
if the gains and the phases of the reflection characteristic and the transmission characteristic are the first pattern, the calculation unit uses the transmission characteristic, and
if the gains and the phases of the reflection characteristic and the transmission characteristic are the second pattern, the calculation unit uses the reflection characteristic.

3. The analysis device according to claim 2, wherein
if the gains and the phases of the reflection characteristic and the transmission characteristic are the first pattern, the phase of the reflection characteristic is less than 180 degrees, and
if the gains and the phases of the reflection characteristic and the transmission characteristic are the second pattern, the phase of the reflection characteristic is 180 degrees or more.

4. The analysis device according to claim 2, wherein if the gains and the phases of the reflection characteristic and the transmission characteristic are the first pattern, the calculation unit regards that 2Z₀/R is 0, where Z₀ is characteristic impedance of a transmission line of the circuit, and R is resistance of the resistor.

5. The analysis device according to claim 2, wherein if the gains and the phases of the reflection characteristic and the transmission characteristic are the first pattern, the calculation unit regards that |(2LZ₀/R²)s| is 0, where L is inductance of the inductor, Z₀ is characteristic impedance of a transmission line of the circuit, R is resistance of the resistor, and s is Laplace transform variable.

6. The analysis device according to claim 2, wherein if the gains and the phases of the reflection characteristic and the transmission characteristic are the second pattern, the calculation unit does not regard that 2Z₀/R is 0, where Z₀ is characteristic impedance of a transmission line of the circuit, and R is resistance of the resistor.

7. A non-transitory recording medium storing an analysis program, which allows a computer to function as:
an extraction unit configured to use reflection characteristic and transmission characteristic included in S-parameters of a DUT measured by a series-through measurement method with a frequency characteristic measurement device, so as to extract a pole frequency, a zero point frequency, and a low frequency part of gain that can be approximated as a DC component, from gains and phases of the reflection characteristic and the transmission characteristic; and
a calculation unit configured to calculate circuit constants of an equivalent circuit of the DUT, from the pole frequency, the zero point frequency, and the low frequency part, wherein
the equivalent circuit is a circuit assumed to be consisting of a capacitor connected in parallel with a serial connection body of a resistor and an inductor.

8. An analysis device comprising:
an extraction unit configured to use reflection characteristic and transmission characteristic included in S-parameters of a DUT measured by a shunt-through measurement method with a frequency characteristic measurement device, so as to extract a pole frequency, a zero point frequency, and a low frequency part of gain that can be approximated as a DC component, from gains and phases of the reflection characteristic and the transmission characteristic; and
a calculation unit configured to calculate circuit constants of an equivalent circuit of the DUT, from the pole frequency, the zero point frequency, and the low frequency part, wherein
the equivalent circuit is a circuit assumed to be consisting of a capacitor connected in parallel with a serial connection body of a resistor and an inductor.

9. The analysis device according to claim 8, wherein
patterns of the gains and the phases of the reflection characteristic and the transmission characteristic include a first pattern and a second pattern,
if the gains and the phases of the reflection characteristic and the transmission characteristic are the first pattern, the calculation unit uses the reflection characteristic, and
if the gains and the phases of the reflection characteristic and the transmission characteristic are the second pattern, the calculation unit uses the transmission characteristic.

10. The analysis device according to claim 9, wherein
if the gains and the phases of the reflection characteristic and the transmission characteristic are the first pattern, the phase of the transmission characteristic is less than 180 degrees,
if the gains and the phases of the reflection characteristic and the transmission characteristic are the second pattern, the phase of the transmission characteristic is 180 degrees or more.

11. The analysis device according to claim 9, wherein if the gains and the phases of the reflection characteristic and the transmission characteristic are the first pattern, the calculation unit regards that Z₀/(2R) is 0, where Z₀ is characteristic impedance of a transmission line of the circuit, and R is resistance of the resistor.

12. The analysis device according to claim 9, wherein if the gains and the phases of the reflection characteristic and the transmission characteristic are the first pattern, the calculation unit regards that |(LZ₀/(2R²))s| is 0, where Lis inductance of the inductor, Z₀ is characteristic impedance of a transmission line of the circuit, R is resistance of the resistor, and s is Laplace transform variable.

13. The analysis device according to claim 9, wherein if the gains and the phases of the reflection characteristic and the transmission characteristic are the second pattern, the calculation unit does not regard that Z₀/(2R) is 0, where Z₀ is characteristic impedance of a transmission line of the circuit, and R is resistance of the resistor.

14. A non-transitory recording medium storing an analysis program, which allows a computer to function as:
an extraction unit configured to use reflection characteristic and transmission characteristic included in S-parameters of a DUT measured by a shunt-through measurement method with a frequency characteristic measurement device, so as to extract a pole frequency, a zero point frequency, and a low frequency part of gain that can be approximated as a DC component, from gains and phases of the reflection characteristic and the transmission characteristic; and
a calculation unit configured to calculate circuit constants of an equivalent circuit of the DUT, from the pole frequency, the zero point frequency, and the low frequency part, wherein
the equivalent circuit is a circuit assumed to be consisting of a capacitor connected in parallel with a serial connection body of a resistor and an inductor.
